(19) United States
(12) Patent Application Publication
(10) Pub. No.: US 2004/0041573 A1
(43) Pub. Date: Mar. 4, 2004

(54) Method and circuit for measuring a voltage or a temperature and for generating a voltage with any predeterminable temperature dependence

(76) Inventors: Torsten Klemm, D-65812 Bad Soden (DE); Gunther Bergk, D-65527 Niederhausen (DE)

Correspondence Address: Robert C Nabinger, Fish & Richardson, 225 Franklin Street, Boston, MA, 02110-2804, US

(21) Appl. No.: 10/297,868

(22) PCT Filed: Jun. 20, 2001
(86) PCT No.: PCT/EP01/06972

(51) Int. Cl. G01R 27/08

(52) U.S. Cl. 324/713

(57) ABSTRACT

The invention relates to a method and a circuit for measuring a voltage and a temperature and for generating a voltage with adjustable temperature dependence.

The method according to the invention comprises the following steps:

determining a first measured value (M1) for a first forward voltage (U_{(I1,T)}) of a pn-transition, through which a first current (I1) flows, of a semiconductor component;

determining a second measured value (M2) for a second forward voltage (U_{(I2,T)}) of the same pn-transition, but through which a second current (I2) flows;

calculating a value, which is proportional to the voltage (U₀, U_{(I1,T)}, U_{(I2,T)}) to be measured, from the determined measured values (M1, M2) from at least one parameter (n) which characterises the pn-transition, and optionally from the desired temperature dependence.

The circuit according to the invention comprises an A/D converter (W), a semiconductor component (D) with a pn-transition, and a voltage source for supplying a first and a second current (I1; I2) via the pn-transition, wherein the pn-transition is situated parallel to the input of the A/D converter (W). The output of the A/D converter is connected to an arithmetic circuit.

The invention relates to a method and a circuit for measuring a voltage and/or a temperature and for generating a voltage with any predeterminable temperature dependence.

It is the object of the present invention to disclose a simple method for measuring a voltage and/or a temperature and for generating a voltage with any predeterminable temperature dependence, and a particularly simple circuit for implementing the method.

According to the invention, this object is met by a method comprising the following steps: determining a first forward voltage of a pn-transition of a semiconductor component, for example a diode, through which pn-transition a first current flows, and then determining a second forward voltage of the same pn-transition while a second current flows through it, with the magnitude of the two currents preferably differing by several powers of ten. Preferably, the two measurements are taken in immediate sequence so that the same measuring conditions are present at the time both readings are taken, i.e. that the temperature of the pn-transition is the same, and the supply voltage of the circuit used for implementing the method is constant. Subsequently, by means of a arithmetic circuit, a value which is proportional to the voltage to be measured is determined from the measured values and a parameter which characterises the pn-transition. This parameter is given by the relationship of temperature drifts in the forward voltages when the first and the second current are applied respectively.

This parameter can also be derived from the family of characteristics of the pn-transition.

Suitable proportionality factors are required for calculating the absolute value of the voltages to be measured. In order to determine the temperature, the arithmetic circuit needs to know the relationship between the temperature and the forward voltage of the pn-transition at least in the case of one current. This relationship is described by further parameters which characterise the pn-transition, which parameters can be determined from the family of characteristics of the pn-transition. From the temperature calculated, a voltage with a predetermined temperature dependence can be calculated. The desired temperature dependence is determined by further parameters or by a function.

A circuit according to the invention comprises an A/D converter, a controllable switch, a semiconductor component with a pn-transition, for example a diode, a voltage source, an arithmetic circuit and a control circuit for the controllable switch and the A/D converter. A current which is supplied by the voltage source and whose size can be switched between two values by the controllable switch can flow through the pn-transition. After each switch-over, the A/D converter scans the forward voltage which occurs at the pn-transition and supplies corresponding digital measured values. From the digital measured values and the parameters which characterise the pn-transition, the arithmetic circuit can calculate a value which is proportional to the forward voltage of the pn-transition, a value which is proportional to the supply voltage of the A/D converter, or if necessary, by means of suitable proportionality factors, said arithmetic circuit can also calculate their absolute value, as well as the temperature of the pn-transition. From the temperature, a voltage with any predeterminable temperature dependence can subsequently be calculated, and, if need be, issued in analog or digital form. Preferably, the parameters and the proportionality factors are stored in the arithmetic circuit. The relationship between the forward voltage of the pn-transition at the selected current and the temperature of the pn-transition, which relationship is required to determine the temperature, as well as the desired temperature dependence of the voltage to be generated, are stored in a way which is known per se, for example in a table or as a formula, also preferably in the arithmetic circuit or in a memory which the arithmetic circuit can access.

With the method or circuit according to the invention, a temperature-dependent voltage U_{(T)} can be generated whose temperature dependence can be set. Such a voltage can for example be used for controlling the discharging/charging process of an accumulator. However, the method or the circuit according to the invention can also be used to measure the battery voltage or accumulator voltage and/or temperature of a battery-operated or accumulator-operated device. In devices which comprise a microcontroller, the invention provides a special advantage in that these measurements can also be carried out using a microcontroller which comprises neither a reference voltage connection nor an internal circuit for generating a temperature-compensated reference voltage, and which is thus particularly economical.

Below, the invention is explained by means of embodiments of circuits according to the invention, and the determination of the parameters required in the method according to the invention is described by means of a family of characteristics. The following are shown:

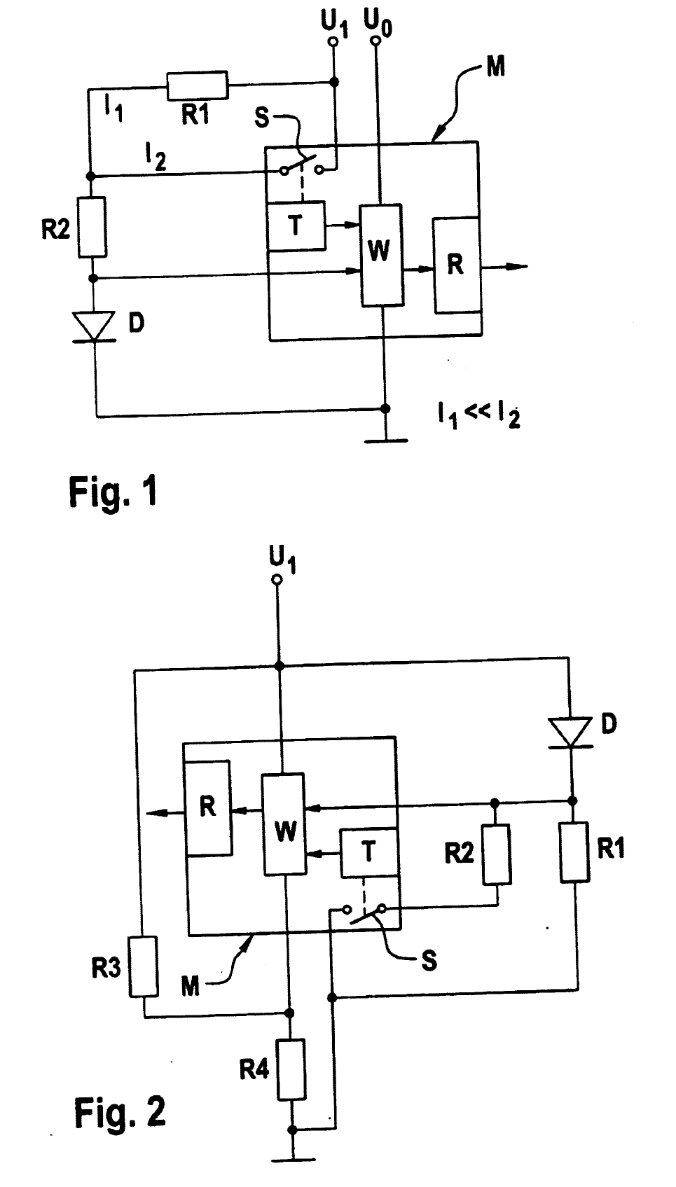

FIG. 1 a diagrammatic view of a first circuit according to the invention;

FIG. 2 a diagrammatic view of a second circuit according to the invention;

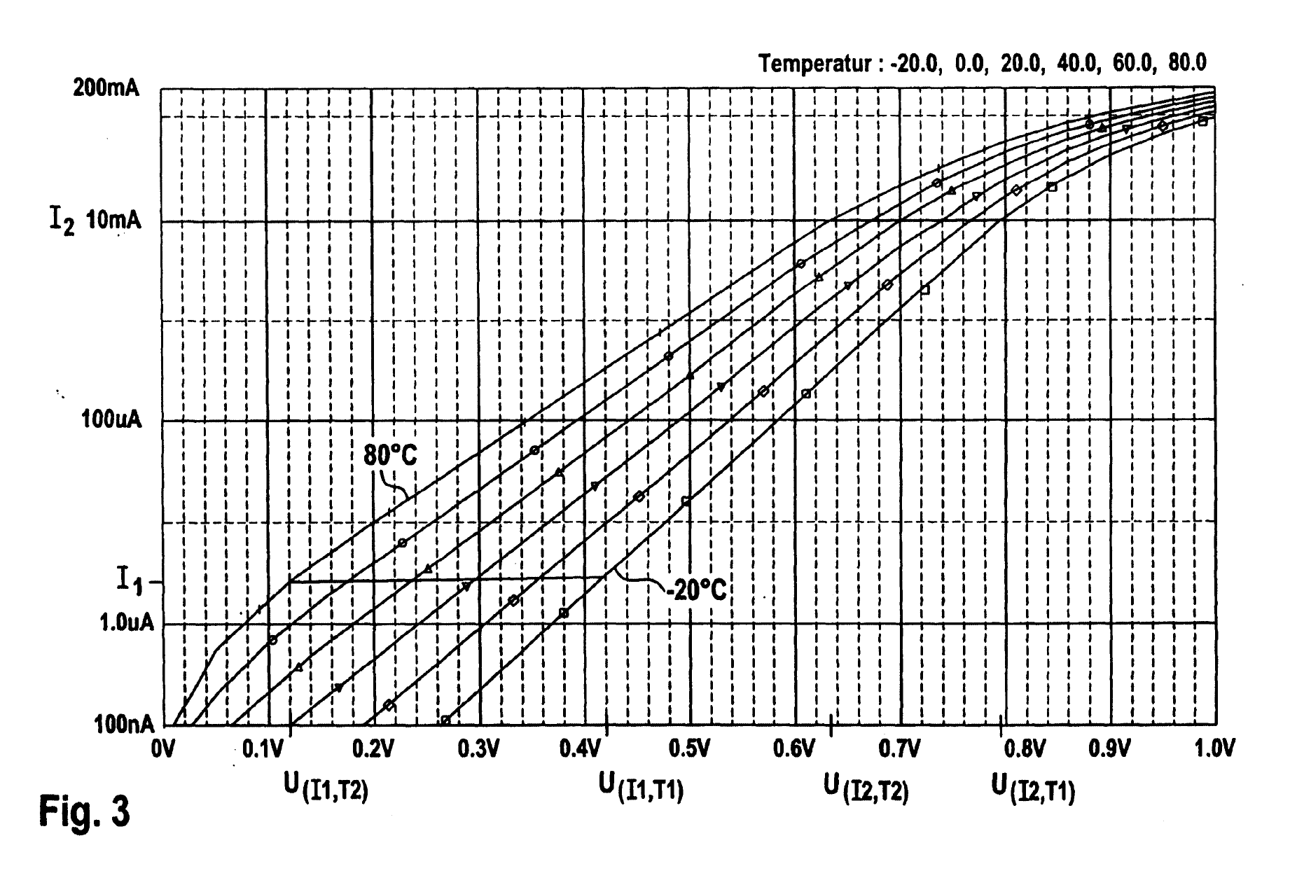

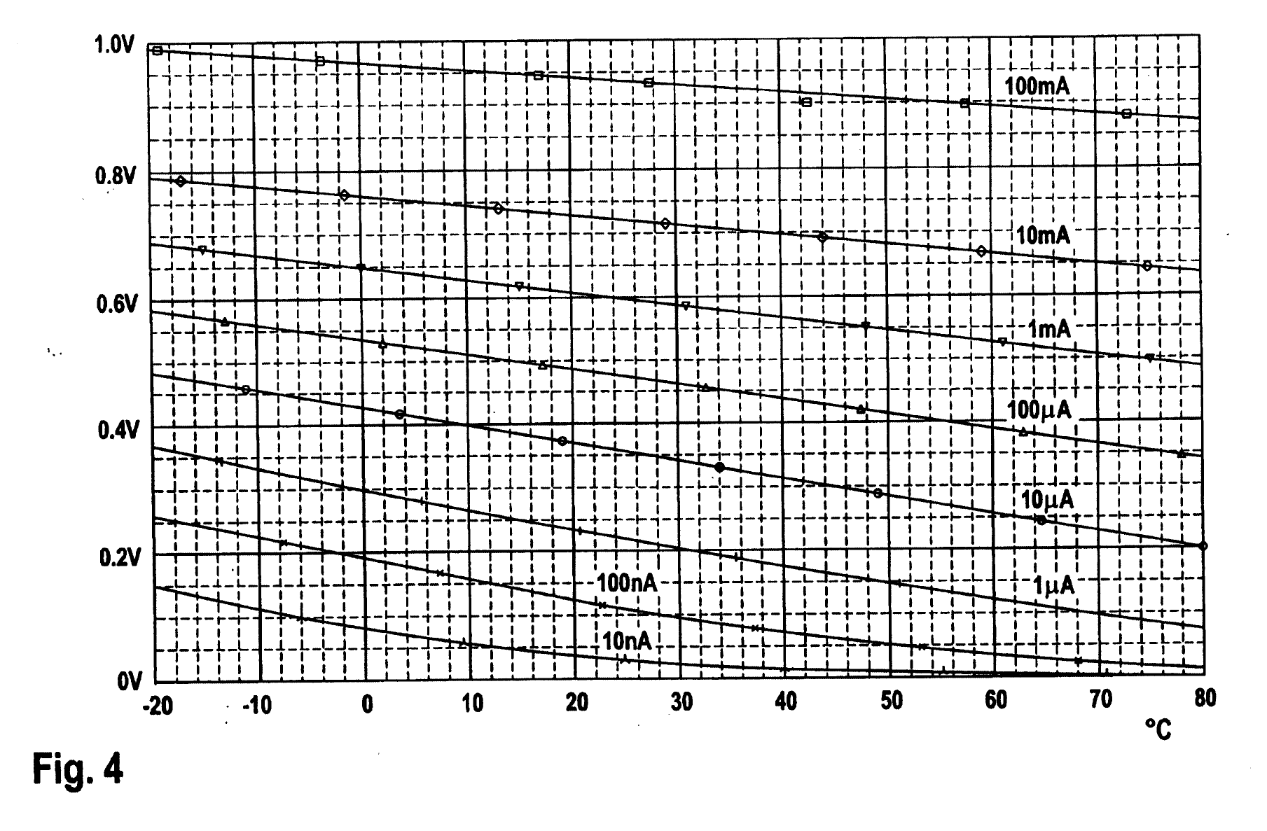

FIG. 3 a family of characteristics of a pn-transition of a semiconductor component; and

FIG. 4 another view of the family of characteristics according to FIG. 3.

The circuit according to the invention, shown in FIG. 1, comprises an A/D converter W which is supplied by a voltage U_{O} from a voltage source, said voltage being related to the mass. The input of the A/D converter W is connected to mass via a pn-transition, which is switched in the direction of flow, of a semiconductor component, with said semiconductor component being a diode D. A further voltage source with the voltage U₁ is connected, via a first and a second resistor R1, R2 and via a controllable switch S and the second resistor R2, to the input of the A/D converter W. When the switch S is open, a first current I1 can flow via the first and second resistor R1, R2, and when the switch S is closed, a second current 12 can flow via the switch S and the second resistor R2 through the diode D. The controllable switch S can be controlled by a clock pulse signal generated by a control circuit T, with said clock pulse signal also being fed to the A/D converter W. The output of the A/D converter W is connected to an arithmetic circuit R which can comprise an analog and/or a digital output at which the desired voltage can be tapped off or to which a display device (not shown in the Figure) can be connected. The controllable switch S, the control circuit T, the arithmetic circuit R and the A/D converter W are preferably integrated in a microcontroller M. With this circuit, a first forward voltage of the diode D can be measured, while with the switch S open, a first current I1 flows through it, and a second forward voltage of the same diode D can be measured, while with the switch S closed, a second current I2 flows through it, with the magnitude of the two currents I1, I2 preferably differing by several powers of ten. The voltages U₁, U₀ of the voltage sources, and the resistors R1, R2 are dimensioned such that on the one hand the desired currents I1 and I2 result, and on the other hand the voltage at the input of the A/D converter W never exceeds its supply voltage U₀.

In a variant of the circuit according to the invention, shown in FIG. 1, the voltages U₁, U₀ of the two voltage sources are the same, i.e. instead of two voltage sources there is only one. In this case, the resolution of the A/D converter must be higher, if the same measuring accuracy is to be achieved as is the case with a circuit comprising two voltage sources.

In order to generate a voltage with any predeterminable temperature dependence according to the invention, first the desired temperature dependence is programmed as a function into the circuit or stored as a table in a memory. Preferably, the parameters are also stored in the same place, said parameters describing the characteristics of the pn-transition used. The determination of said characteristics is explained below by means of the family of characteristics of a pn-transition, shown in FIG. 3. Said family of characteristics reflects the relationship between the forward voltage of the pn-transition and the current flowing through the pn-transition at various temperatures of the pn-transition in semi-logarithmic representation. In this representation, the above-mentioned relationship is linear over a large area.

From the linear area of the family of characteristics, for two differently selected currents I1, I2 at two differently selected temperatures T1, T2, a forward voltage each, U_{(I,T)}, i.e. a total of four forward voltages U_{(I1,T1)}, U_{(I1,T2)}, U_{(I2,T1)}, U_{(I2,T2)} are taken. As can be seen from the family of characteristics, the temperature drifts ΔU of the forward voltages

ΔU_{(I1)}=U_{(I1,T2)}−U_{(I1,T1)} and

ΔU_{(I2)}=U_{(I2,T2)}−U_{(I2,T1)} (1)

differ in the selected currents I1, I2 and temperatures T1, T2 by a temperature-independent factor n, which represents a first parameter characterising the pn-transition:

n=ΔU_{(I1)}|ΔU_{(I2)} (2)

By inserting (1) and transforming (2) we arrive at

n*U_{(I2,T2)}−U_{(I1,T2)}=n*U_{(I2,T1)}−U_{(I1,T1)}=k (3)

wherein k is a temperature-independent constant which represents a second parameter that characterises the pn-transition. As can be seen from the family of characteristics, the parameters n and k do not depend on whether, through the diode D of the circuit according to the invention, instead of the selected currents I1, I2, for example due to a fluctuating supply voltage, currents flow which are smaller or larger by a particular factor, than are the selected currents I1, I2. However, n and k do depend on the relationship 11/12. Families of characteristics of other semiconductor components, for example of a pn-transition of a transistor, can be evaluated in the same way.

With the parameter n, the circuit can determine a value which is proportional to the supply voltage U₀ of the A/D converter at any temperature of the pn-transition, or it can determine a value which is proportional to the temperature of the pn-transition at any supply voltage U₀. If in addition, a particular temperature function is entered in the arithmetic circuit, it can calculate a voltage with the respective temperature dependence and if required issue it at one of its outputs in analog or digital form.

First, determination of the supply voltage U₀ with the circuit shown in FIG. 1 is explained. At its output, the A/D converter supplies a measured value M_{(T)} if a voltage U_{(T)} is present at its input (provided no overflow of the A/D converter occurs):

M_{(T)}=Mₘₐₓ*U_{(T)}/U₀ (4)

wherein U₀ is the supply voltage of the A/D converter and Mₘₐₓ is the largest value which can be represented by the A/D converter. Analogously, the following applies to the input voltages U_{(I1,T)}, U_{(I2,T)} and the corresponding measured values M1_{(T)}, M2_{(T)}:

U_{(I1,T)}=M1_{(T)}*U₀/Mₘₐₓ and U_{(I2,T)}=M2_{(T)}*U₀/Mₘₐₓ (5)

If (5) is inserted in (3), the following results:

n*M2_{(T)}*U₀/Mₘₐₓ−M1_{(T)}*U₀/Mₘₐₓ=k, or

U₀=k*Mₘₐₓ/(n*M2_{(T)}−M1_{(T)}) (6)

Equation (6) states that the supply voltage U₀ of the value l/(n*M2_{(T)}−M1_{(T)}) determined from the measured values M1, M2 is proportional to k*Mₘₐₓ as a proportionality factor. Determination of U₀ is independent of the temperature of the pn-transition, because k/(n*M2_{(T)}−M1_{(T)}) is temperature-independent (compare equation 3).

Below, determination of the temperature T of the pn-transition with the circuit shown in FIG. 1 is explained. If (6) is inserted in (4), we arrive at

U_{(T)}=k*M_{(T)}/(n*M2_{(T)}−M1_{(T)}) (7)

wherein the temperature dependence of the voltage U_{(T)} is defined by the characteristics of the pn-transition, as shown in FIG. 4. According to FIG. 4, the relationship between the temperature T and the forward voltage U_{(I,T)} of the pn-transition is largely linear, i.e. in the linear area of the family of characteristics, the forward voltages U_{(I1,T)} and U_{(I2,T)} are proportional to the temperature T. Thus, after inserting (6) in (5), the following results:

U_{(I1,T)}=k*M1_{(T)}/(n*M2_{(T)}−M1_{(T)})=a₁*T+b₁

and

U_{(I2,T)}=k*M2_{(T)}/(n*M2_{(T)}−M1_{(T)})=a₂*T+b₂ (8)

or

U_{(I2)}/a₂−b₂/a₂=T_{(U)}=U_{(I1)}/a₁−b₁/a₁ (9)

The parameters a₁, b₁ or a₂, b₂ can be determined from the family of characteristics of the pn-transition; preferably they are stored, together with parameters n and k, in the arithmetic circuit or in a memory to which the arithmetic circuit has access. Thus, in order to determine the absolute value of the temperature T of the pn-transition, the forward voltage U_{(I1,T)} or U_{(I2,T)} is measured using the method according to the invention, and subsequently the temperature T is calculated. Determining the temperature T is independent of the size of the supply voltage U₀.

In order to generate a voltage U_{(T)}, which can have any temperature dependence, the desired temperature dependence of the voltage must be programmed for example as a function U_{(T)} in the arithmetic circuit or it must be stored as a table in a memory to which the arithmetic circuit has access. Preferably, the table or programming can be changed as desired by way of an input device. After the temperature has been determined by means of equation (9), the voltage U_{(T)} with the corresponding temperature dependence can be calculated by the arithmetic circuit and can be output in analog or digital form.

If for example a voltage U_{(T)}=a*T+b with defined parameters a, b is to be generated, then for example at first at temperature T′, the forward voltage U_{(I2,T′)} is determined according to equation (8). The desired voltage U_{(T′)} then results from equation (9) as follows:

U_{(T′)}=U_{(I2, T′)}*a/a₂−b₂*a/a₂+b.

The circuit according to the invention, shown in FIG. 2, mainly differs from the circuit described with reference to FIG. 1 in that the input of the A/D converter W via diode D is not connected to mass but to the voltage source U1, and in that the input of the A/D converter W via the first and second resistor R1, R2 and the controllable switch S is not connected to the voltage source but instead, is connected to mass. However, the first and second resistor R1, R2 are not connected in series, instead, the second resistor R2 is connected in series with the controllable switch S. The first resistor R1 is situated parallel to this. Thus, when the switch S is open, the first current I1 flows via the first resistor R1, while when the switch S is closed, the second current 12 flows via both resistors R1, R2 and the switch S through diode D. Furthermore, only one voltage source U1 exists which provides the supply voltage U₀ of the A/D converter via a voltage divider which is formed from a third and fourth resistor R3, R4.

In a variant of the circuit according to the invention, shown in FIG. 2, there are no third and fourth resistors R3, R4, i.e. the A/D converter is positioned between the voltage source U1 and the mass. In this case, the resolution of the A/D converter must be higher, if the same measuring accuracy as that in the circuit according to the invention, shown in FIG. 2, is to be attained.

Calculation of the supply voltage U₀, to be measured with the circuit shown in FIG. 2, of the A/D converter W and/or of the temperature T of the diode D is explained below. At its output, the A/D converter W delivers a measured value M if the voltage U drops at diode D, and thus, if at the input of the A/D converter W a voltage U₀−U is present (provided the forward voltage U of diode D never exceeds the supply voltage U₀ of the A/D converter)

M=Mₘₐₓ*(U₀−U)/U₀ (4′)

wherein U₀ is the supply voltage of the A/D converter and Mₘₐₓ is the largest value which can be represented by the A/D converter. Analogously, the following applies to the input voltages U_{(I1)}, U_{(I2)} and the corresponding measured values M1, M2:

U_{(I1)}=U₀−M1*U₀/Mₘₐₓ and

U_{(I2)}=U₀−M2*U₀/Mₘₐₓ (5′)

If (5′) is inserted in (3), the following results:

U₀=k*Mₘₐₓ/(n(Mₘₐₓ−M2)−(Mₘₐₓ−M1)) (6′)

If (6′) is inserted in (5′), the following applies to the forward voltages U_{(I1)} and U_{(I2)} with current I1 and I2 respectively:

U_{(I1)}=k*(Mₘₐₓ−M1)/(n(Mₘₐₓ−M2)−(Mₘₐₓ−M1))

and

U_{(I2)}=k*(Mₘₐₓ−M2)/(n(Mₘₐₓ−M2)−(Mₘₐₓ−M1)) (8′)

A comparison of the relationships (6′), (8′) with the relationships (6), (8) shows that, with the circuit according to FIG. 2, calculation of the voltages to be measured takes place in exactly the same way as with the circuit according to FIG. 1, except that the measured values M1, M2 are to be replaced by (Mₘₐₓ−M1) or (Mₘₐₓ−M2) respectively.

1. A method for measuring a voltage,
characterised by the following steps:
determining a first measured value (M1) for a first forward voltage (U_{(I1,T)}) of a pn-transition, through which a first current (I1) flows, of a semiconductor component;
determining a second measured value (M2) for a second forward voltage (U_{(I2,T)}) of the same pn-transition, but through which a second current (I2) flows;
calculating a value, which is proportional to the voltage (U₀, U_{(I1,T)}, U_{(I2,T)} to be measured, from the determined measured values (M1, M2) and from a parameter (n) which characterises the pn-transition.

2. The method according to claim 1,
characterised in that
the parameter (n) represents the relationship of the temperature drifts (ΔU_{(I1)}, ΔU_{(I2)}) of the forward voltages with the selected currents (I1, I2).

3. The method according to claim 1 or 2,
characterised in that
the magnitude of the two currents (I1, I2) preferably differs by several powers of ten.

4. The method according to claim 1, 2 or 3,
characterised in that
the voltage (U₀, U_{(I1,T)}, U_{(I2,T)} to be measured is calculated from the proportional value and a proportionality factor.

5. A method for measuring a temperature,
characterised by the following steps:
measuring a forward voltage (U_{(I,T)}) of a pn-transition of a semiconductor component at a predetermined current (I) by means of the method for measuring a voltage according to any one of the preceding claims; and
calculating the temperature (T) of the pn-transition from the measured forward voltage (U_{(I,T)}) and a previously determined relationship between the temperature and the forward voltage (U_{(I,T)}) of the pn-transition at the predetermined current (I).

6. A method for generating a voltage with a predeterminable temperature dependence,
characterised by the following steps:
determining the temperature of a pn-transition of a semiconductor component according to claim 5; and
calculating the voltage with the predetermined temperature dependence from the determined temperature and the predetermined temperature dependence.

7. A circuit for measuring a voltage, a temperature and/or for generating a voltage with predeterminable temperature dependence, in particular for implementing the method according to any one of the preceding claims,
characterised in that
it comprises an A/D converter (W), a semiconductor component (D) with a pn-transition and a voltage source for supplying a first and a second current (I1; I2) through the pn-transition, wherein the pn-transition is situated parallel to the input of the A/D converter (W), and in that it comprises an arithmetic circuit (R) which is connected to the output of the A/D converter (W).

8. The circuit according to claim 7,
characterised in that
it further comprises a controllable switch (S) and a control circuit (T) for controlling the controllable switch (S) and the A/D converter (W), and in that the magnitude of the current (I1; I2) supplied by the voltage source, can be switched by the controllable switch (S).

9. The circuit according to claim 7 or 8,
characterised in that
there is a memory in which the parameters which characterise the pn-transition and or characterise the predeterminable temperature dependence can be stored, and in that the arithmetic circuit (R) can access the memory.
